(19) United States
(12) Patent Application Publication
(10) Pub. No.: US 2025/0321274 A1
(43) Pub. Date: Oct. 16, 2025

(54) DIAGNOSTIC DEVICE FOR SWITCHING ELEMENT AND ABNORMALITY DETECTION CIRCUIT

(71) Applicant: YAZAKI CORPORATION, Tokyo (JP)

(72) Inventors: Shintaro Muramatsu, Susono-shi (JP); Takaaki Izawa, Susono-shi (JP)

(21) Appl. No.: 19/251,634

(22) Filed: Jun. 26, 2025

Related U.S. Application Data
(63) Continuation of application No. PCT/JP2024/035104, filed on Oct. 1, 2024.

(30) Foreign Application Priority Data
Oct. 23, 2023 (JP) 2023-181539

(51) Int. Cl. G01R 31/327; H02J 9/06

(52) U.S. Cl. CPC G01R 31/3275; H02J 9/061

(57) ABSTRACT

A diagnostic device includes a microcomputer that outputs a pseudo signal for simulating an abnormal state to an overvoltage detection circuit and a low voltage detection circuit, and a detection circuit that detects ON of a switching element after the pseudo signal is output by the microcomputer. The microcomputer determines a failure of the switching element or failures of the overvoltage detection circuit and the low voltage detection circuit when ON of the switching element is detected by the detection circuit.

### CROSS-REFERENCE TO RELATED APPLICATIONS

This is a continuation of International Application No. PCT/JP2024/035104 filed on Oct. 1, 2024, and claims priority from Japanese Patent Application No. 2023-181539 filed on Oct. 23, 2023, the entire content of which is incorporated herein by reference.

### TECHNICAL FIELD

The present disclosure relates to a diagnostic device for a switching element and an abnormality detection circuit.

### BACKGROUND ART

A failure detection device that detects a failure of a switching element while ensuring a conduction state is known (see Patent Literature 1). In the failure detection device described in Patent Literature 1, a plurality of FET circuit units are connected in parallel, and in each FET circuit unit, a pair of FETs are connected in series and arranged in opposite directions. In the failure detection device, while one pair of FETs of the plurality of FET circuit units are controlled to be on, a failure of another pair of FETs of the plurality of FET circuit units is detected based on an on/off control state of the other pair of FETs of the plurality of FET circuit units and a voltage of a conductive path between FETs.

### CITATION LIST

### Patent Literature

### Patent Literature 1: JP2022-74827A

### SUMMARY OF INVENTION

In the failure detection device described in Patent Literature 1, a failure diagnosis on FETs is executed while ensuring a conduction state and supplying power to a load, but a failure diagnosis on an abnormality detection circuit such as an overvoltage detection circuit and an overcurrent detection circuit is not executed.

The present disclosure is made in view of the above circumstance, and an object of the present disclosure is to provide a diagnostic device for a switching element and an abnormality detection circuit, which can execute a failure diagnosis on the switching element and the abnormality detection circuit while supplying power from a backup storage battery to a backup load in a redundant system including a redundant load and a redundant storage battery.

According to the present disclosure, there is provided a diagnostic device for executing a failure diagnosis on a first switching element and an abnormality detection circuit in a redundant system. The redundant system includes a first storage battery that supplies power to a first load, a second storage battery that supplies power to a second load when an abnormality occurs to the first storage battery, a first power line that connects the second load and the first storage battery, the first switching element provided on the first power line, a second power line that connects the second storage battery and a connection point between the first switching element and the second load on the first power line, a second switching element provided on the second power line, the abnormality detection circuit that detects an abnormal state on the first power line or the second power line, and a driver that turns off the first switching element when the abnormal state is detected by the abnormality detection circuit. The diagnostic device includes: a first signal output unit configured to output a pseudo signal for simulating the abnormal state to the abnormality detection circuit; a detection unit configured to detect ON of the first switching element after the pseudo signal is output by the first signal output unit; a determination unit configured to determine a failure of the first switching element or a failure of the abnormality detection circuit when ON of the first switching element is detected by the detection unit; a first current cut switch provided on a third power line connecting the first power line and the abnormality detection circuit; and a second signal output unit that outputs a first release signal for releasing a current cutoff by the first current cut switch to the first current cut switch before the pseudo signal is output by the first signal output unit.

According to the present disclosure, it is possible to execute a failure diagnosis on a switching element and an abnormality detection circuit while supplying power from a backup storage battery to a backup load in a redundant system including a redundant load and a redundant storage battery.

### BRIEF DESCRIPTION OF DRAWINGS

FIG. 1 is a circuit diagram showing a diagnostic device according to an embodiment of the present disclosure;

FIG. 2 is a flowchart showing a process when executing a failure diagnosis on a switching element, an overvoltage detection circuit, and a low voltage detection circuit; and

FIG. 3 is a timing chart showing waveforms of various signals when executing the failure diagnosis on the switching element, the overvoltage detection circuit, and the low voltage detection circuit.

### DESCRIPTION OF EMBODIMENTS

Hereinafter, the present disclosure will be described with reference to a preferred embodiment. The present disclosure is not limited to the embodiment to be described below, and the embodiment to be described below can be appropriately changed within a scope not departing from the spirit of the present disclosure. In the embodiment to be described below, a part of configurations may not be described or shown in the drawings, and regarding details of omitted techniques, publicly known or well-known techniques will be appropriately applied as long as there is no contradiction with contents to be described below.

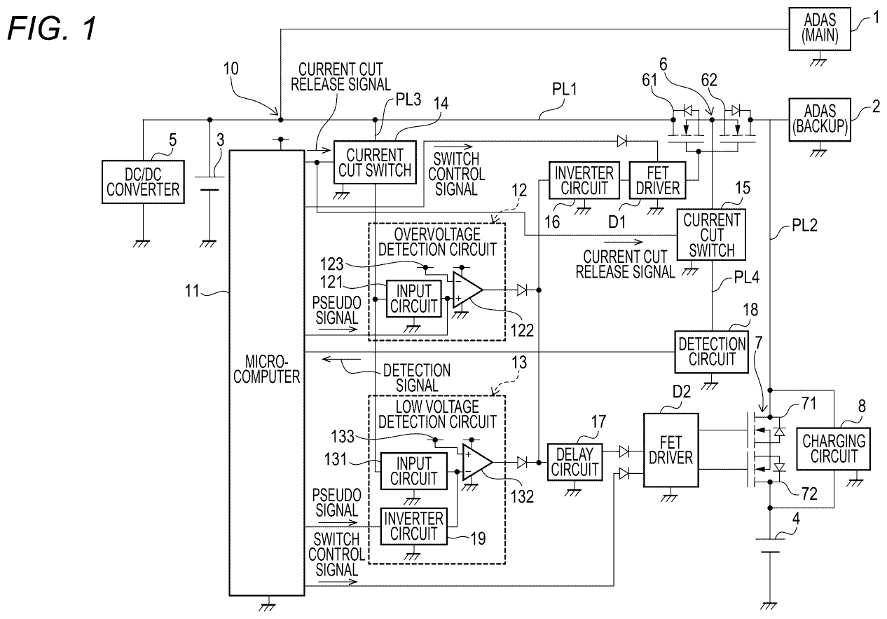

FIG. 1 is a circuit diagram showing a diagnostic device 10 according to the embodiment of the present disclosure. A diagnostic device 10 shown in the drawing is mounted on a vehicle redundantly including advanced driver assistant systems (hereinafter, ADAS) 1, 2, a main battery 3, and a backup battery 4. In the vehicle, the main ADAS 1 driven in a normal state and the backup ADAS 2 driven when an abnormality occurs in the ADAS 1 are connected in parallel to a DC/DC converter 5. The main battery 3 and the backup battery 4 are also connected in parallel to the DC/DC converter 5.

The main battery 3 is a secondary battery such as a lead storage battery, and is charged with power supplied from the DC/DC converter 5. The backup battery 4 is a secondary battery such as a lithium-ion storage battery, and is charged with power supplied from the DC/DC converter 5 or the main battery 3. The DC/DC converter 5 steps down an output voltage of a high voltage power supply (not shown) to a voltage of the main battery 3 and the backup battery 4.

A first switch 6 is provided on a power line PL1 connecting the backup ADAS 2 and the DC/DC converter 5. The first switch 6 includes a pair of switching elements 61, 62. The switching elements 61, 62 are field effect transistors (FET) such as metal-oxide-semiconductor field effect transistors (MOSFET).

The switching element 61 and the switching element 62 have sources thereof connected to each other. The switching element 61 has a drain thereof connected to the DC/DC converter 5 and a positive electrode of the main battery 3. The switching element 62 has a drain thereof connected to the backup ADAS 2 and a second switch 7 described later.

The switching element 61 and the switching element 62 have gates thereof connected to a FET driver D1, which applies a high/low voltage between the gate and the source of each of the switching elements 61, 62 with reference to the source. The switching elements 61, 62 are turned on when a high level voltage equal to or higher than an operation threshold is applied between the gate and the source by the FET driver D1. On the other hand, the switching elements 61, 62 are turned off when a high level voltage equal to or higher than the operation threshold is not applied between the gate and the source by the FET driver D1. Here, in a state in which a current from the drain to the source of each of the switching elements 61, 62 is cut off, the first switch 6 cuts off a bidirectional current.

The second switch 7 is provided on a power line PL2 that connects the backup ADAS 2 and the drain of the switching element 62 to the backup battery 4. The second switch 7 includes a pair of switching elements 71, 72. The switching elements 71, 72 are field effect transistors such as MOSFET.

The switching element 71 and the switching element 72 have sources thereof connected to each other. The switching element 71 has a drain thereof connected to the backup ADAS 2 and the drain of the switching element 62. The switching element 72 has a drain thereof connected to a positive electrode of the backup battery 4.

The switching element 71 and the switching element 72 have gates thereof connected to a FET driver D2, which applies a high/low voltage between the gate and the source of each of the switching elements 71, 72 with reference to the source. The switching elements 71, 72 are turned on when a high level voltage equal to or higher than an operation threshold is applied between the gate and the source by the FET driver D2. On the other hand, the switching elements 71, 72 are turned off when a high level voltage equal to or higher than the operation threshold is not applied between the gate and the source by the FET driver D2. Here, in a state in which a current from the drain to the source of each of the switching elements 71, 72 is cut off, the second switch 7 cuts off a bidirectional current.

The second switch 7 and a charging circuit 8 are connected in parallel to the power line PL2. While the first switch 6 is on and the second switch 7 is off, the charging circuit 8 charges the backup battery 4 with a current supplied from the DC/DC converter 5 or the main battery 3.

The main ADAS 1 is connected between a connection point of the main battery 3 and a connection point of the switching element 61 on the power line PL1. The power line PL2 is connected between a connection point of the switching element 62 and a connection point of the backup ADAS 2 on the power line PL1.

The vehicle redundantly including the ADAS 1, 2, the main battery 3, and the backup battery 4 further includes an overvoltage detection circuit 12 and a low voltage detection circuit 13. The overvoltage detection circuit 12 detects an overvoltage state of the power line PL1 or the power line PL2. The low voltage detection circuit 13 detects an abnormally low voltage state of the power line PL1 or the power line PL2.

The overvoltage detection circuit 12 includes an input circuit 121, a comparator 122, and a reference voltage unit 123. The input circuit 121 has an input terminal thereof connected between a connection point of the main battery 3 and a connection point of the switching element 61 on the power line PL1 via a current cut switch 14 described later. The input circuit 121 has an output terminal thereof connected to an input terminal (+IN) of the comparator 122.

The comparator 122 has an input terminal (−IN) thereof connected to the reference voltage unit 123, and an output terminal thereof connected to an input terminal of an inverter circuit 16 and an input terminal of a delay circuit 17. The comparator 122 has a positive-side power supply terminal thereof connected to the main battery 3 or the like, and a negative-side power supply terminal thereof grounded.

The input circuit 121 is a voltage divider that divides a voltage of the power line PL1 or the power line PL2 and outputs the divided voltage to the input terminal (+IN) of the comparator 122. When a voltage between the main battery 3 and the first switch 6 on the power line PL1 is an overvoltage, a voltage value indicated by an output signal of the input circuit 121 is larger than a voltage value indicated by an output signal of the reference voltage unit 123. On the other hand, when the voltage of the power line PL1 or the power line PL2 is normal, the voltage value indicated by the output signal of the input circuit 121 is smaller than the voltage value indicated by the output signal of the reference voltage unit 123.

The comparator 122 outputs a high level signal from the output terminal to the inverter circuit 16 and the delay circuit 17 when a voltage value indicated by an input signal of the input terminal (+IN) is larger than a voltage value indicated by an input signal of the input terminal (−IN). That is, when the voltage of the power line PL1 or the power line PL2 is an overvoltage, a high level signal is output from the comparator 122 to the inverter circuit 16 and the delay circuit 17.

On the other hand, the comparator 122 outputs a low level signal from the output terminal to the inverter circuit 16 and the delay circuit 17 when the voltage value indicated by the input signal of the input terminal (−IN) is larger than the voltage value indicated by the input signal of the input terminal (+IN). That is, when the voltage of the power line PL1 or the power line PL2 is normal, a low level signal is output from the comparator 122 to the inverter circuit 16 and the delay circuit 17.

The low voltage detection circuit 13 includes an input circuit 131, a comparator 132, and a reference voltage unit 133. The input circuit 131 has an input terminal thereof connected between the connection point of the main battery 3 and the connection point of the switching element 61 on the power line PL1 via the current cut switch 14. The input circuit 131 has an output terminal thereof connected to an input terminal (−IN) of the comparator 132. The comparator 132 has an input terminal (+IN) thereof connected to the reference voltage unit 133, and an output terminal thereof connected to the input terminal of the inverter circuit 16 and the input terminal of the delay circuit 17. The comparator 132 has a positive-side power supply terminal thereof connected to the main battery 3 or the like, and a negative-side power supply terminal thereof grounded.

The input circuit 131 is a voltage divider that divides the voltage of the power line PL1 or the power line PL2 and outputs the divided voltage to the input terminal (−IN) of the comparator 132. When the voltage of the power line PL1 or the power line PL2 is an abnormally low voltage, a voltage value indicated by an output signal of the input circuit 131 is smaller than a voltage value indicated by an output signal of the reference voltage unit 133. On the other hand, when the voltage of the power line PL1 or the power line PL2 is normal, the voltage value indicated by the output signal of the input circuit 131 is larger than the voltage value indicated by the output signal of the reference voltage unit 133.

The comparator 132 outputs a high level signal from the output terminal to the inverter circuit 16 and the delay circuit 17 when a voltage value indicated by an input signal of the input terminal (−IN) is smaller than a voltage value indicated by an input signal of the input terminal (+IN). That is, when the voltage of the power line PL1 or the power line PL2 is an abnormally low voltage, a high level signal is output from the comparator 132 to the inverter circuit 16 and the delay circuit 17.

On the other hand, the comparator 132 outputs a low level signal from the output terminal to the inverter circuit 16 and the delay circuit 17 when the voltage value indicated by the input signal of the input terminal (−IN) is larger than the voltage value indicated by the input signal of the input terminal (+IN). That is, when the voltage of the power line PL1 or the power line PL2 is normal, a low level signal is output from the comparator 132 to the inverter circuit 16 and the delay circuit 17.

The inverter circuit 16 inverts polarity of the output signals of the comparators 122, 132 and outputs the inverted signals to the FET driver D1. When the voltage of the power line PL1 or the power line PL2 is an overvoltage, the high level signal output from the comparator 122 is inverted and a low level signal is output to the FET driver D1. The FET driver DI sets the voltage applied to the gates of the switching elements 61, 62 to be a low level voltage less than the operation threshold, and turns off the first switch 6.

On the other hand, when the voltage of the power line PL1 or the power line PL2 is normal, the inverter circuit 16 inverts the low level signal output from the comparator 122 and outputs a high level signal to the FET driver D1. The FET driver DI sets the voltage applied to the gates of the switching elements 61, 62 to be a high level voltage equal to or higher than the operation threshold, and turns on the first switch 6.

When the voltage of the power line PL1 or the power line PL2 is an abnormally low voltage, the inverter circuit 16 inverts the high level signal output from the comparator 132 and outputs a low level signal to the FET driver D1. The FET driver DI sets the voltage applied to the gates of the switching elements 61, 62 to be a low level voltage less than the operation threshold, and turns off the first switch 6.

On the other hand, when the voltage of the power line PL1 or the power line PL2 is normal, the inverter circuit 16 inverts the low level signal output from the comparator 132 and outputs a high level signal to the FET driver D1. The FET driver DI sets the voltage applied to the gates of the switching elements 61, 62 to be a high level voltage equal to or higher than the operation threshold, and turns on the first switch 6.

The delay circuit 17 is a circuit that delays signals output from the comparators 122, 132 to the FET driver D2. The delay circuit 17 prevents the first switch 6 and the second switch 7 from being turned on at the same time.

The diagnostic device 10 includes a microcomputer 11, current cut switches 14, 15, a detection circuit 18, and an inverter circuit 19. The microcomputer 11 is a control device that controls the overvoltage detection circuit 12, the low voltage detection circuit 13, the current cut switches 14, 15, and the FET drivers D1, D2. The microcomputer 11 has a positive-side terminal thereof connected to a power source such as the main battery 3, and a negative terminal thereof grounded.

The microcomputer 11 outputs a pseudo signal to the input terminal (+IN) of the comparator 122 when executing a failure diagnosis on the first switch 6 and the overvoltage detection circuit 12. The pseudo signal is a signal indicating a voltage value larger than the voltage value indicated by the output signal of the reference voltage unit 123. For this reason, when the overvoltage detection circuit 12 operates normally, the voltage value indicated by the input signal of the input terminal (+IN) of the comparator 122 is larger than the voltage value indicated by the input signal of the input terminal (−IN) of the comparator 122, and a high level signal is output from the comparator 122 to the inverter circuit 16 and the delay circuit 17. In this case, the inverter circuit 16 inverts the high level signal output from the comparator 122 and outputs a low level signal to the FET driver D1. The FET driver DI sets the voltage applied to the gates of the switching elements 61, 62 to be a low level voltage less than the operation threshold, and turns off the first switch 6.

The microcomputer 11 outputs a pseudo signal to the input terminal (−IN) of the comparator 132 when executing the failure diagnosis on the low voltage detection circuit 13.

The pseudo signal is a high level signal indicating a voltage value larger than the voltage value indicated by the output signal of the reference voltage unit 133. The pseudo signal is inverted by the inverter circuit 19 to a low level signal indicating a voltage value smaller than the voltage value indicated by the output signal of the reference voltage unit 133, and is input to the input terminal (−IN) of the comparator 132. For this reason, when the low voltage detection circuit 13 operates normally, the voltage value indicated by the input signal of the input terminal (−IN) of the comparator 132 is smaller than the voltage value indicated by the input signal of the input terminal (+IN) of the comparator 122, and a high level signal is output from the comparator 132 to the inverter circuit 16 and the delay circuit 17. In this case, the inverter circuit 16 inverts the high level signal output from the comparator 132 and outputs a low level signal to the FET driver D1. The FET driver DI sets the voltage applied to the gates of the switching elements 61, 62 to be a low level voltage less than the operation threshold, and turns off the first switch 6.

The current cut switch 14 is provided on a power line PL3 that connects the input circuits 121, 131 to the power line PL1. The current cut switch 14 cuts off the power line PL3 except when the failure diagnosis on the switching elements 61, 62, the overvoltage detection circuit 12, and the low voltage detection circuit 13 is executed and when the overvoltage detection circuit 12 and the low voltage detection circuit 13 are operating, for example, when the vehicle is traveling. On the other hand, the microcomputer 11 outputs a current cut release signal to the current cut switch 14 to release the cutoff of the power line PL3 by the current cut switch 14 except when the vehicle is parked.

The current cut switch 15 is provided on a power line PL4 that connects the detection circuit 18 and a common source of the first switch 6. The current cut switch 15 cuts off the power line PL4 during parking. On the other hand, the microcomputer 11 outputs a current cut release signal to the current cut switch 15 to release the cutoff of the power line PL4 by the current cut switch 15 except when the vehicle is parked.

The detection circuit 18 is a circuit that detects ON of the first switch 6 according to a voltage of the common source of the switching elements 61, 62 of the first switch 6. The detection circuit 18 outputs a high level detection signal to the microcomputer 11 when the voltage of the common source of the switching elements 61, 62 is equal to or higher than a threshold. On the other hand, the detection circuit 18 outputs a low level detection signal to the microcomputer 11 when the voltage of the common source of the switching elements 61, 62 is less than the threshold. The threshold is set at a small value larger than 0 V but close to 0 V to determine whether the switching elements 61, 62 are turned on.

When executing the failure diagnosis on the switching elements 61, 62 and the overvoltage detection circuit 12, the microcomputer 11 outputs a current cut release signal to the current cut switches 14, 15 and outputs a pseudo signal to the overvoltage detection circuit 12. When the switching elements 61, 62 and the overvoltage detection circuit 12 operate normally, the switching elements 61, 62 are turned off, and a low level detection signal is output from the detection circuit 18. On the other hand, when at least one of the switching elements 61, 62 and the overvoltage detection circuit 12 fails, the switching elements 61, 62 have remained ON, and a high level detection signal is output from the detection circuit 18. When the high level detection signal is output from the detection circuit 18, the microcomputer 11 determines an ON failure of the switching elements 61, 62 or a failure of the overvoltage detection circuit 12.

When executing the failure diagnosis on the switching elements 61, 62 and the low voltage detection circuit 13, the microcomputer 11 outputs a current cut release signal to the current cut switches 14, 15 and outputs a pseudo signal to the low voltage detection circuit 13.

When the switching elements 61, 62 and the low voltage detection circuit 13 operate normally, the switching elements 61, 62 are turned off, and a low level detection signal is output from the detection circuit 18. On the other hand, when at least one of the switching elements 61, 62 and the low voltage detection circuit 13 fails, the switching elements 61, 62 are remained on, and a high level detection signal is output from the detection circuit 18. When the high level detection signal is output from the detection circuit 18, the microcomputer 11 determines an ON failure of the switching elements 61, 62 or a failure of the low voltage detection circuit 13.

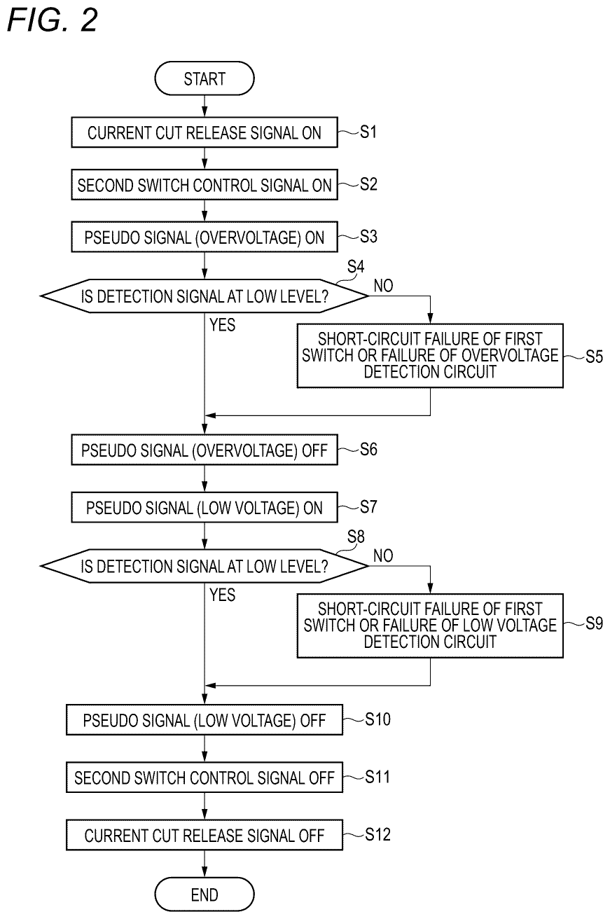

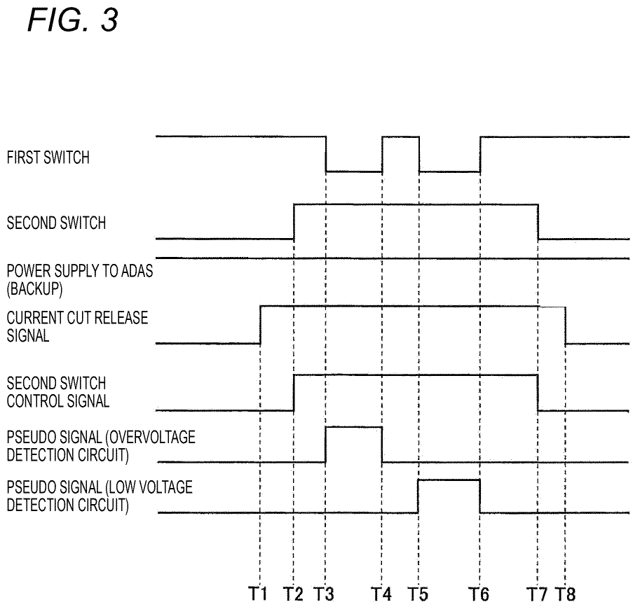

FIG. 2 is a flowchart showing a process when executing a failure diagnosis on the switching elements 61, 62, the overvoltage detection circuit 12, and the low voltage detection circuit 13. FIG. 3 is a timing chart showing waveforms of various signals when the failure diagnosis is executed.

When executing the failure diagnosis, first, the microcomputer 11 turns on the current cut release signal output to the current cut switches 14, 15 (step S1 in FIG. 2, T1 in FIG. 3). Accordingly, the cutoff of the power line PL3 by the current cut switch 14 and the cutoff of the power line PL4 by the current cut switch 15 are released, the overvoltage detection circuit 12 and the low voltage detection circuit 13 are connected to the power line PL1, and the detection circuit 18 is connected to the common source of the switching elements 61, 62.

Next, the microcomputer 11 turns on (high level) a switch control signal for the second switch 7 output to the FET driver D2 (step S2 in FIG. 2, T2 in FIG. 3). Accordingly, the second switch 7 is turned on, and the backup battery 4 is connected to the backup ADAS 2.

Next, the microcomputer 11 turns on the pseudo signal output to the input terminal (+IN) of the comparator 122 of the overvoltage detection circuit 12 (step S3 in FIG. 2, T3 in FIG. 3). Next, the microcomputer 11 determines whether the detection signal output from the detection circuit 18 is at a low level (step S4 in FIG. 2). When the detection signal output from the detection circuit 18 is at a high level (NO in step S4 in FIG. 2), the microcomputer 11 determines a short-circuit failure (ON failure) of the switching elements 61, 62 or a failure of the overvoltage detection circuit 12 (step S5 in FIG. 2). On the other hand, when the detection signal output from the detection circuit 18 is at the low level (YES in step S4 in FIG. 2), the microcomputer 11 turns off the pseudo signal (step S6 in FIG. 2, T4 in FIG. 3).

Next, the microcomputer 11 turns on the pseudo signal output to the input terminal (−IN) of the comparator 132 of the low voltage detection circuit 13 (step S7 in FIG. 2, T5 in FIG. 3). Next, the microcomputer 11 determines whether the detection signal output from the detection circuit 18 is at a low level (step S8 in FIG. 2). When the detection signal output from the detection circuit 18 is at a high level (NO in step S8 in FIG. 2), the microcomputer 11 determines a short-circuit failure of the switching elements 61, 62 or a failure of the low voltage detection circuit 13 (step S9 in FIG. 2). On the other hand, when the detection signal output from the detection circuit 18 is at the low level (YES in step S8 in FIG. 2), the microcomputer 11 turns off the pseudo signal (step S10 in FIG. 2, T6 in FIG. 3).

Next, the microcomputer 11 turns off (low level) the switch control signal for the second switch 7 output to the FET driver D2 (step S11 in FIG. 2, T7 in FIG. 3). Accordingly, the second switch 7 is turned off, and the backup battery 4 is cut off from the backup ADAS 2.

Finally, the microcomputer 11 turns off the current cut release signal output to the current cut switches 14, 15 (step S12 in FIG. 2, T8 in FIG. 3). Accordingly, the current cut switch 14 cuts off the power line PL3, and the current cut switch 15 cuts off the power line PL4. Therefore, the overvoltage detection circuit 12 and the low voltage detection circuit 13 are cut off from the power line PL1, and the detection circuit 18 is cut off from the first switch 6. This is an end of the failure diagnosis process.

As described above, the diagnostic device 10 according to the present embodiment executes the failure diagnosis on the switching elements 61, 62, the overvoltage detection circuit 12, and the low voltage detection circuit 13 of a redundant system. The redundant system includes the main battery 3, the backup battery 4, the power line PL1, the switching elements 61, 62, the power line PL2, the switching elements 71, 72, the overvoltage detection circuit 12, the low voltage detection circuit 13, and the FET driver D1.

The main battery 3 supplies power to the main ADAS 1, and the backup battery 4 supplies power to the backup ADAS 2. The power line PL1 connects the backup ADAS 2 and the main battery 3, and the first switch 6 including the switching elements 61, 62 is provided on the power line PL1. The power line PL2 connects a connection point between the first switch 6 and the backup ADAS 2 on the power line PL1 and the backup battery 4, and the second switch 7 including the switching elements 71, 72 is provided on the power line PL2.

The overvoltage detection circuit 12 detects a state of an overvoltage generated on the power line PL1 or the power line PL2, and the low voltage detection circuit 13 detects a state of a low voltage generated on the power line PL1 or the power line PL2. The FET driver DI turns off the first switch 6 when the overvoltage detection circuit 12 detects an overvoltage state or the low voltage detection circuit 13 detects a low voltage state.

The diagnostic device 10 includes the microcomputer 11 and the detection circuit 18. The microcomputer 11 outputs a pseudo signal for simulating an abnormal state such as an overvoltage or a low voltage generated on the power line PL1 or the power line PL2 to the overvoltage detection circuit 12 and the low voltage detection circuit 13. After the microcomputer 11 outputs the pseudo signal, the detection circuit 18 detects ON of the switching elements 61, 62 of the first switch 6. When the detection circuit 18 detects ON of the switching elements 61, 62 of the first switch 6, the microcomputer 11 determines a failure of the switching elements 61, 62 of the first switch 6 or failures of the overvoltage detection circuit 12 and the low voltage detection circuit 13.

Accordingly, it is possible to execute the failure diagnosis on the switching elements 61, 62 of the first switch 6 and abnormality detection circuits such as the overvoltage detection circuit 12 and the low voltage detection circuit 13 in a state in which the backup battery 4 is connected to the backup ADAS 2 and redundancy between the ADAS 1, 2, the main battery 3, and the backup battery 4 is ensured.

In the diagnostic device 10 according to the present embodiment, the current cut switch 14 is provided on the power line PL3 that connects the power line PL1 and the abnormality detection circuits such as the overvoltage detection circuit 12 and the low voltage detection circuit 13. The microcomputer 11 outputs a current cut release signal for releasing a current cutoff by the current cut switch 14 to the current cut switch 14 before the pseudo signal is output. Accordingly, a dark current supplied from the main battery 3 to the abnormality detection circuits can be cut off except when the failure diagnosis is executed, and power consumption can be reduced.

In the diagnostic device 10 according to the present embodiment, the current cut switch 15 is provided on the power line PL4 that connects the switching elements 61, 62 of the first switch 6 and the detection circuit 18. The microcomputer 11 outputs a current cut release signal for releasing a current cutoff by the current cut switch 15 to the current cut switch 15 before the pseudo signal is output. Accordingly, a dark current supplied from the main battery 3 to the detection circuit 18 can be cut off except when the overvoltage detection circuit 12 and the low voltage detection circuit 13 are operating, for example, when the failure diagnosis is executed and when the vehicle is traveling, and the power consumption can be reduced.

The present disclosure has been described based on the above-described embodiment, but the present disclosure is not limited to the embodiment described above, and modifications may be made to the embodiment described above, and publicly known or well-known techniques may be appropriately combined within a scope not departing from the spirit of the present disclosure.

For example, in the above embodiment, a load having redundancy includes the ADAS 1, 2. Alternatively, the load having redundancy may include another load such as power steering. Further, in the above embodiment, the abnormality detection circuits include the overvoltage detection circuit 12 and the low voltage detection circuit 13. Alternatively, the abnormality detection circuits may include another circuit such as an overcurrent detection circuit that detects an overcurrent of the power line PL1 or an overheat detection circuit that detects overheat of the power line PL1.

Although an embodiment has been described above, it is needless to say that the present disclosure is not limited to this example. It is apparent that those skilled in the art can come up with various modifications or corrections within the scope of the claims, and it is understood that the modifications or corrections naturally fall within the technical scope of the present disclosure. In addition, components described in the above embodiment may be combined freely without departing from the spirit of the invention.

The present application is based on a Japanese patent application (No. 2023-181539A) filed on Oct. 23, 2023, contents of which are incorporated herein by reference.

What is claimed is:

1. A diagnostic device for executing a failure diagnosis on a first switching element and
an abnormality detection circuit in a redundant system,
the redundant system including
a first storage battery that supplies power to a first load,
a second storage battery that supplies power to a second load when an abnormality occurs to the first storage battery,
a first power line that connects the second load and the first storage battery,
the first switching element provided on the first power line,
a second power line that connects the second storage battery and a connection point between the first switching element and the second load on the first power line,
a second switching element provided on the second power line,
the abnormality detection circuit that detects an abnormal state on the first power line or the second power line, and
a driver that turns off the first switching element when the abnormal state is detected by the abnormality detection circuit,
the diagnostic device comprising:
a first signal output unit that outputs a pseudo signal for simulating the abnormal state to the abnormality detection circuit;
a detection unit that detects ON of the first switching element after the pseudo signal is output by the first signal output unit;
a determination unit that determines a failure of the first switching element or a failure of the abnormality detection circuit when ON of the first switching element is detected by the detection unit;
a first current cut switch provided on a third power line connecting the first power line and the abnormality detection circuit; and
a second signal output unit that outputs a first release signal for releasing a current cutoff by the first current cut switch to the first current cut switch before the pseudo signal is output by the first signal output unit.

2. A diagnostic device for executing a failure diagnosis on a first switching element and an abnormality detection circuit in a redundant system,
the redundant system including
a first storage battery that supplies power to a first load,
a second storage battery that supplies power to a second load when an abnormality occurs to the first storage battery,
a first power line that connects the second load and the first storage battery,
the first switching element provided on the first power line,
a second power line that connects the second storage battery and a connection point between the first switching element and the second load on the first power line,
a second switching element provided on the second power line,
the abnormality detection circuit that detects an abnormal state on the first power line or the second power line, and
a driver that turns off the first switching element when the abnormal state is detected by the abnormality detection circuit,
the diagnostic device comprising:
a first signal output unit that outputs a pseudo signal for simulating the abnormal state to the abnormality detection circuit;
a detection unit that detects ON of the first switching element after the pseudo signal is output by the first signal output unit;
a determination unit that determines a failure of the first switching element or a failure of the abnormality detection circuit when ON of the first switching element is detected by the detection unit;
a second current cut switch provided on a fourth power line connecting the first switching element and the detection unit; and
a third signal output unit that outputs a second release signal for releasing a current cutoff by the second current cut switch to the second current cut switch before the pseudo signal is output by the first signal output unit.

3. A diagnostic device for executing a failure diagnosis on a first switching element and an abnormality detection circuit in a redundant system,
the redundant system including
a first storage battery that supplies power to a first load,
a second storage battery that supplies power to a second load when an abnormality occurs to the first storage battery,
a first power line that connects the second load and the first storage battery,
the first switching element provided on the first power line,
a second power line that connects the second storage battery and a connection point between the first switching element and the second load on the first power line,
a second switching element provided on the second power line,
the abnormality detection circuit that detects an abnormal state on the first power line or the second power line, and
a driver that turns off the first switching element when the abnormal state is detected by the abnormality detection circuit,
the diagnostic device comprising:
a first signal output unit that outputs a pseudo signal for simulating the abnormal state to the abnormality detection circuit;
a detection unit that detects ON of the first switching element after the pseudo signal is output by the first signal output unit; and
a determination unit that determines a failure of the first switching element or a failure of the abnormality detection circuit when ON of the first switching element is detected by the detection unit, wherein
the abnormality detection circuit includes
an overvoltage detection circuit that detects an overvoltage state as the abnormal state, and
a low voltage detection circuit that detects a low voltage state as the abnormal state,
the driver turns off the first switching element when the overvoltage state is detected by the overvoltage detection circuit and when the low voltage state is detected by the low voltage detection circuit.
